(19) United States
(12) Patent Application Publication
(10) Pub. No.: US 2026/0269822 A1
(43) Pub. Date: Sep. 10, 2026

(54) SEMICONDUCTOR DEVICE AND METHOD FOR DRIVING THE SAME

(71) Applicant: Renesas Electronics Corporation, Tokyo (JP)

(72) Inventor: Toru MOCHIDA, Tokyo (JP)

(21) Appl. No.: 19/453,688

(22) Filed: Jan. 20, 2026

(30) Foreign Application Priority Data
Mar. 10, 2025 (JP) 2025-037324

(51) Int. Cl. H03K 17/14; G01R 19/165; G01R 19/32; H03K 3/03

(52) U.S. Cl. CPC H03K 17/14; G01R 19/16533; G01R 19/32; H03K 3/0315; H03K 2217/0027

(57) ABSTRACT

A semiconductor device provides adjustment of circuit characteristics in the field, improvement of yield without taking excessive margins during shipment testing, and reduction of test costs. The semiconductor device equipped with a ring oscillator, a delay monitor circuit that monitors the delay of the target circuit, a voltage monitor circuit that monitors the driving voltage of the target circuit, a calculation circuit that determines whether the threshold voltage of the delay monitor circuit is appropriate using the voltage monitor circuit, and a storage circuit that stores the adjustment voltage to correct the threshold voltage if it is not appropriate.

The disclosure of Japanese Patent Application No. 2025-037324 filed on Mar. 10, 2025, including the specification, drawings and abstract is incorporated herein by reference in its entirety.

### BACKGROUND

The present disclosure relates to a semiconductor device and a method for driving a semiconductor device.

There are disclosed techniques listed below.

[Patent Document 1] Japanese Unexamined Patent Application Publication No. 2018-55511

Patent Document 1 discloses a semiconductor device capable of accurately monitoring the minimum operating voltage of the monitored circuit.

### SUMMARY

However, there was a problem that the circuit monitoring the monitored circuit deteriorates. Therefore, such circuits had to take margins considering deterioration. Accordingly, the purpose of the present disclosure is to provide a semiconductor device that adjusts the characteristics of the circuit in the field (under the environment where the semiconductor device is actually used after shipment), improves yield without taking excessive margins during shipment tests, and improves test costs.

Other objects and novel features will become apparent from the description of this specification and the accompanying drawings.

According to one embodiment, the semiconductor device includes a storage circuit that stores an adjustment voltage for adjusting the threshold voltage.

According to the embodiment, it is possible to provide a semiconductor device that adjusts the characteristics of the circuit in the field, improves yield without taking excessive margins during shipment tests, and improves test costs.

### BRIEF DESCRIPTION OF THE DRAWINGS

FIG. 1 is a block diagram illustrating the functions of the related delay monitor circuit (DMON).

FIG. 2 is a diagram showing the increase in detection voltage due to the deterioration of the related delay monitor circuit.

FIG. 3 is a diagram showing the margin taking into account the characteristic shift of the related delay monitor circuit.

FIG. 4 is a diagram showing the adjustment of the characteristic shift in the field of the delay monitor circuit according to the embodiment.

FIG. 5 is a block diagram illustrating the configuration of the semiconductor device according to the embodiment.

FIG. 6 is a flowchart of the driving method of the semiconductor device according to the embodiment.

FIG. 7 is a diagram showing the case where the semiconductor device according to the embodiment does not deteriorate beyond the deterioration determination criteria.

FIG. 8 is a diagram showing the case where the semiconductor device according to the embodiment is deteriorated beyond the deterioration determination criteria.

### DETAILED DESCRIPTION

For clarity of explanation, the following description and drawings are appropriately omitted and simplified. Also, each element described in the drawings as a functional block performing various processes can be configured by hardware such as a CPU (Central Processing Unit), memory, and other circuits, and can be implemented by software such as programs loaded into memory. Therefore, these functional blocks can be realized by hardware, software operating on hardware, or a combination thereof. In the drawings, the same elements are denoted by the same reference numerals, and a repetitive description thereof is omitted as necessary.

Also, the programs described above may be stored and provided to a computer using various types of non-transitory computer readable media. Non-transitory computer readable media includes various types of tangible storage media. Examples of non-transitory computer-readable media include magnetic recording media (e.g., flexible disks, magnetic tapes, hard disk drives), magneto-optical recording media (e.g., magneto-optical disks), CD-ROM (Read Only Memory, a CD-R, a CD-R/W, solid-state memories (e.g., masked ROM, PROM(Programmable ROM), EPROM (Erasable PROM, flash ROM, RAM (Random Access Memory)). The programs may also be supplied to the computer by various types of transitory computer-readable transitory computer readable media. Examples of transitory computer-readable media include electrical signals, optical signals, and electromagnetic waves. The transitory computer readable medium may provide the program to the computer via wired or wireless communication paths, such as electrical wires and optical fibers.

### Description of the Delay Monitor Circuit

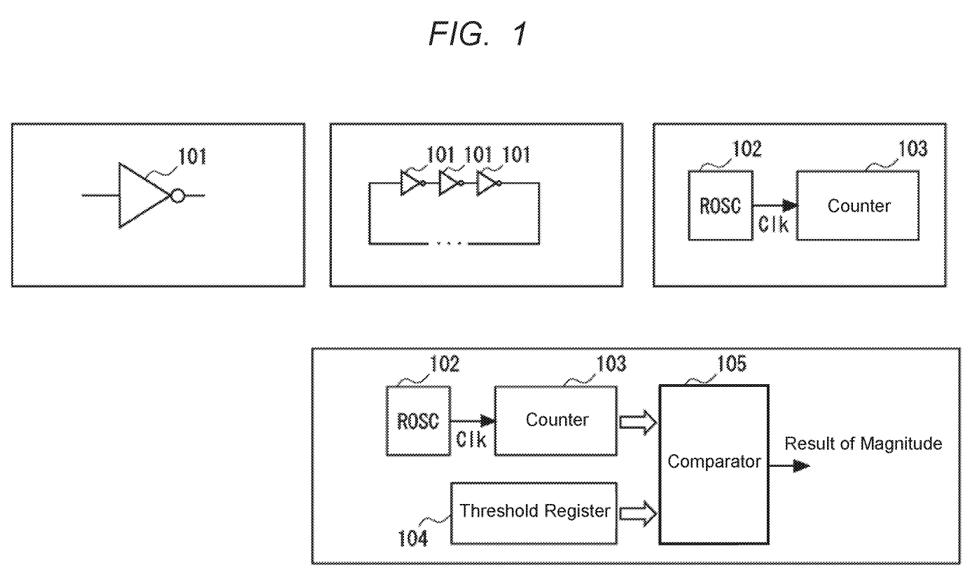

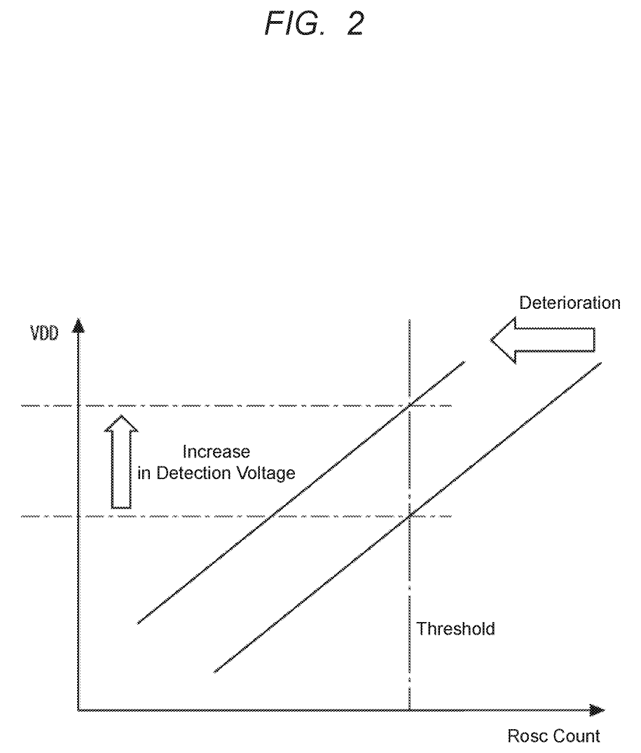

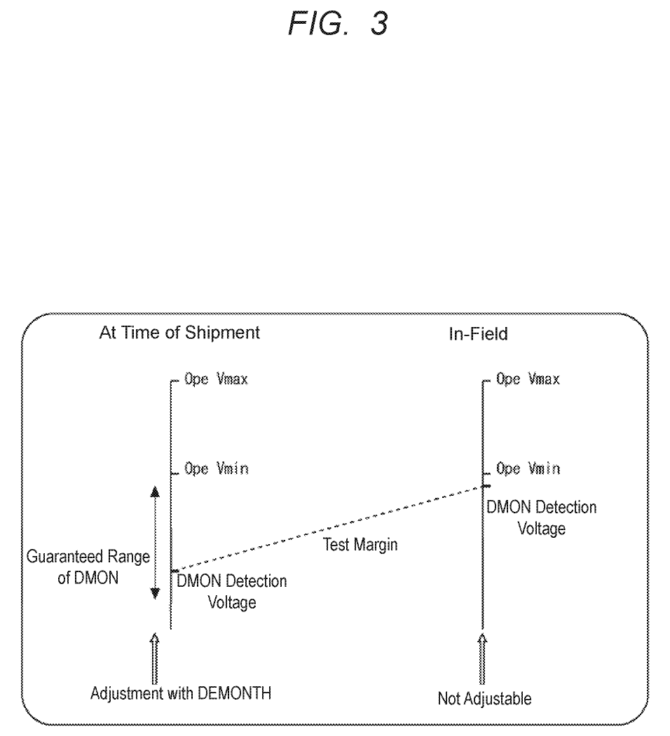

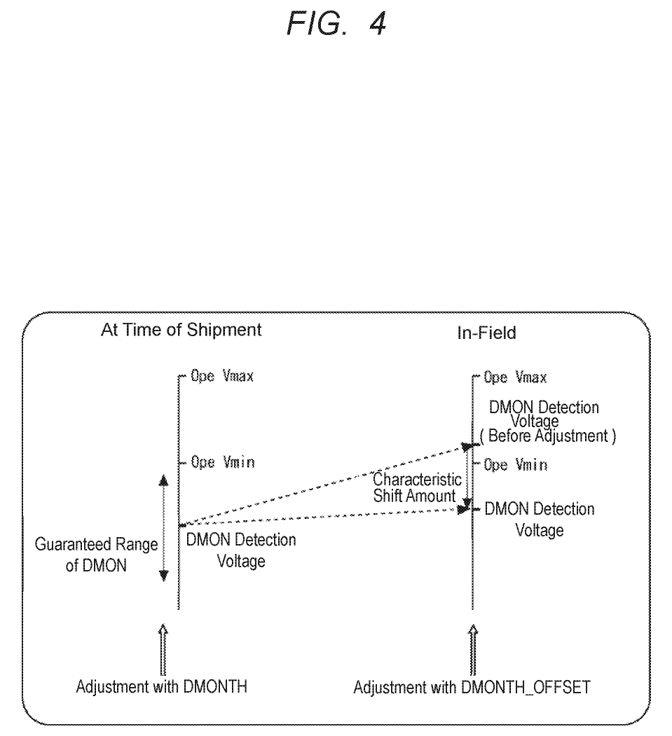

FIG. 1 is a block diagram illustrating the functions of the related delay monitor circuit (DMON). FIG. 2 is a diagram showing the increase in detection voltage due to the deterioration of the related delay monitor circuit. FIG. 3 is a diagram showing the margin taking into account the characteristic shift of the related delay monitor circuit. FIG. 4 is a diagram showing the adjustment of the characteristic shift in the field of the delay monitor circuit according to the embodiment. The delay monitor circuit (DMON) will be described with reference to FIGS. 1 to 4.

The delay monitor circuit (DMON) is a circuit that monitors delay and utilizes the voltage dependency of this delay to realize a power detection function. As shown in the upper left diagram of FIG. 1, the element delay amount has voltage dependency, and the delay monitor circuit (DMON) uses one inverter designed with delay characteristics usable for power detection. This delay circuit is difficult to use.

Therefore, as shown in the middle upper diagram of FIG. 1, the delay element is converted into a ring oscillator 102. Then, the delay can be converted into frequency, but it is still difficult to use. Therefore, as shown in the upper right diagram of FIG. 1, the frequency is converted into a count value using a counter 103 connected to the ring oscillator 102. This allows conversion into a count value with voltage dependency.

As shown in the lower diagram of FIG. 1, when the count value corresponding to the voltage to be detected is set as a threshold in the threshold register and the comparator determines the magnitude, it becomes a power detection circuit.

FIG. 2 shows the ring oscillator (ROSC) count of the delay monitor circuit on the horizontal axis and the detection voltage VDD of the delay monitor circuit on the vertical axis. As indicated by the arrow in FIG. 2, the characteristics of the lower straight line become the characteristics of the upper straight line due to BI and aging, causing the detection voltage to rise at the same threshold.

This is because the deterioration of the transistors constituting the delay monitor circuit increases the element delay amount, and the increase in delay reduces the frequency. The decrease in frequency lowers the count value, necessitating a higher voltage to achieve the same count. In other words, it rises to VDD, which results in a delay equivalent to before deterioration. Therefore, the deterioration of the delay monitor circuit shows a tendency for the detection voltage VDD to rise.

As shown in the left diagram of FIG. 3, a test margin considering the characteristic shift due to deterioration was necessary at the time of shipment of the delay monitor circuit, as shown in the right diagram of FIG. 3. During actual operation, user operation must continue between the maximum operating voltage (Ope Vmax) as the upper limit and the minimum operating voltage (Ope Vmin) as the lower limit, and the delay monitor circuit must not perform false detection. Therefore, considering the voltage shift due to aging, the characteristics of the delay monitor circuit must be set at the lower limit of the guaranteed range at the time of shipment, otherwise it will not fall within the guaranteed range considering the operational years, resulting in no margin. This makes it prone to yield reduction.

As shown in the right diagram of FIG. 4, if the detection voltage of the delay monitor circuit can be adjusted in the field, as shown in the left diagram of FIG. 4, the margin at the time of shipment can be reduced. In other words, there is a margin because the characteristics of the delay monitor circuit can be adjusted to an appropriate detection voltage range in the market without setting it at the lower limit at the time of shipment. Therefore, it is possible to suppress yield reduction due to excessive characteristic assurance and expect cost improvement through yield improvement.

### Description of the Semiconductor Device According to the Embodiment

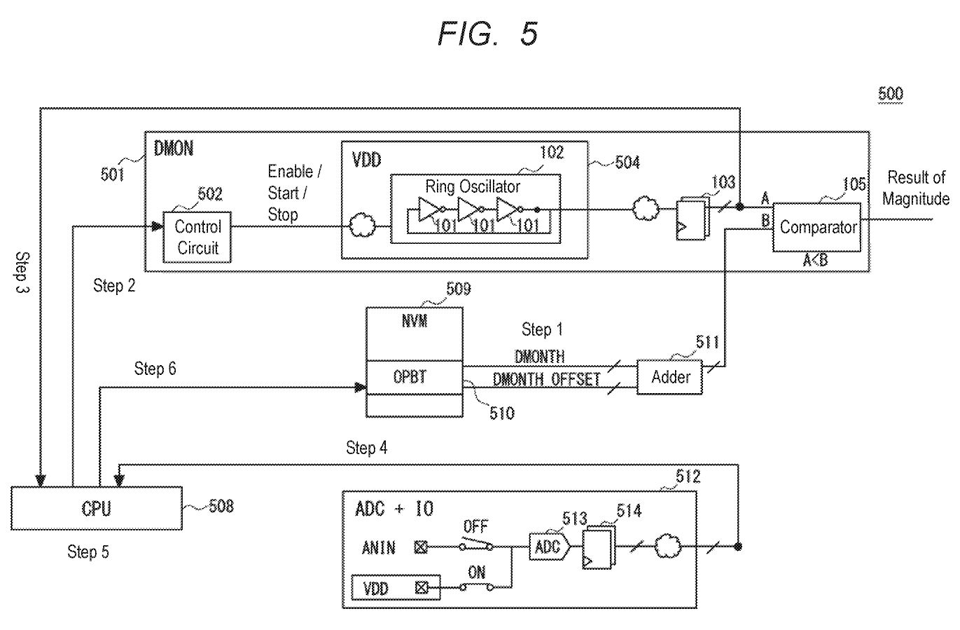

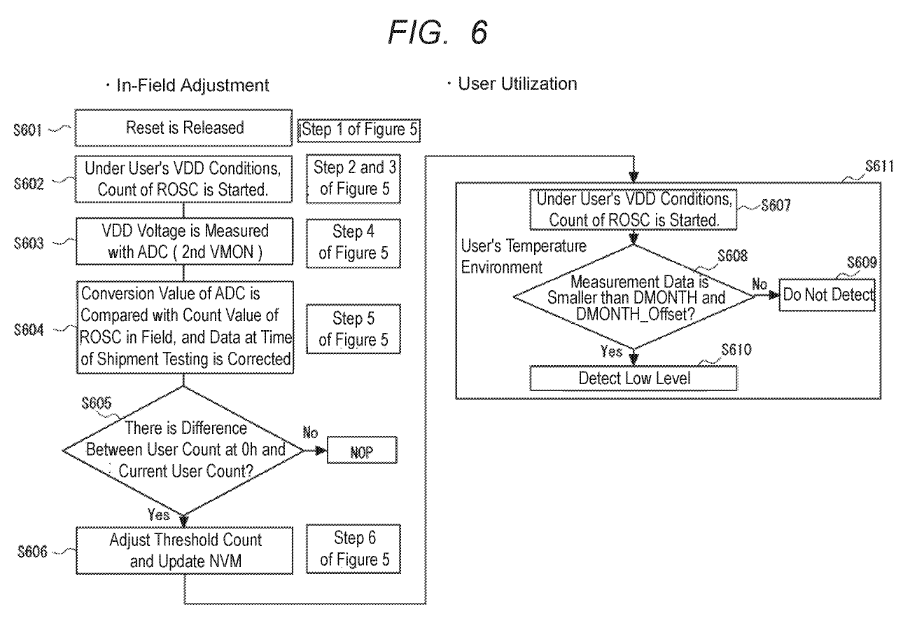

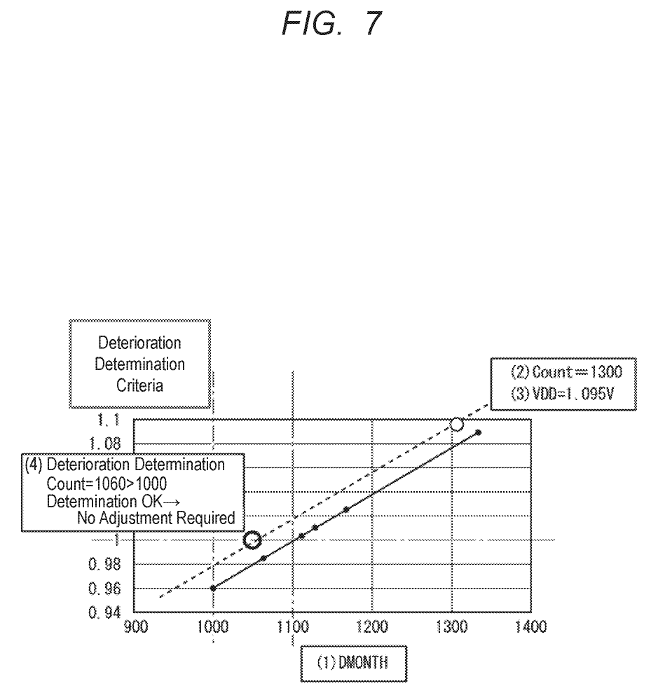

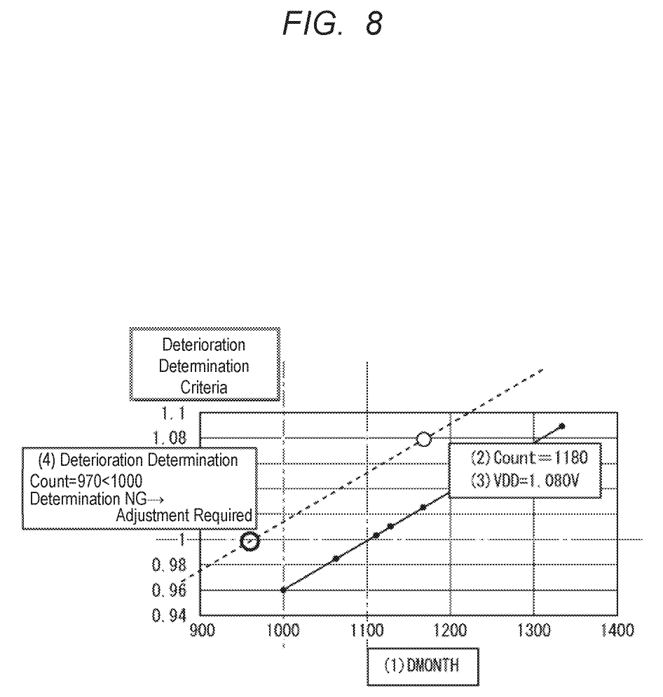

FIG. 5 is a block diagram illustrating the configuration of the semiconductor device according to the embodiment. FIG. 6 is a flowchart of the driving method of the semiconductor device according to the embodiment. FIG. 7 is a diagram showing the case where the semiconductor device according to the embodiment does not deteriorate beyond the deterioration determination criteria. FIG. 8 is a diagram showing the case where the semiconductor device according to the embodiment is deteriorated beyond the deterioration determination criteria. The semiconductor device according to the embodiment will be described with reference to FIGS. 5 to 8.

FIG. 5 shows a semiconductor device 500 that returns the increase in DMON detection voltage due to the deterioration of the CMOS (Complementary Metal Oxide Semiconductor) circuit in the field, which is in the market or in use, to the shipment state. As shown in FIG. 5, the semiconductor device 500 includes a delay monitor circuit (DMON) 501, a CPU (Central Processing Unit) 508, a storage circuit (NVM (Non-Volatile Memory)) 509, an adder 511, an ADC (Analog Digital Converter) 513, and an IO (Input/Output) 512.

The delay monitor circuit 501 has the ring oscillator described above and is a circuit that monitors the delay of the monitored circuit. The delay monitor circuit 501 includes a control circuit 502, a ring oscillator 102 with multiple delay circuits 101, a counter 103, and a comparator 105.

The control circuit 502 is connected to the ring oscillator 102. The control circuit 502 controls the enable, start, and stop of the count of the ring oscillator 102. The ring oscillator 102 is in constant voltage VDD region 504.

The counter 103 is connected to the ring oscillator 102. The counter 103 converts the frequency of the ring oscillator 102 into a count value.

The comparator 105 is connected to counter 103 and the storage circuit 509. Comparator 105 compares the count value output from counter 103 (A in FIG. 5) with the delay monitor circuit threshold stored in the storage circuit 509 (B in FIG. 5). The comparator 105 detects a count value lower than the threshold.

The CPU 508 is connected to the delay monitor circuit 501, the storage circuit 509, the ADC, and the IO 512. The CPU 508 controls the threshold change of the delay monitor circuit 501 in the field.

Specifically, first, the CPU 508 resets the transfer of the delay monitor circuit threshold (Step 1). Next, the CPU 508 instructs the control circuit 502 of the delay monitor circuit 501 to start the count of the ring oscillator of the delay monitor circuit 501 (Step 2). Next, the CPU 508 reads the new count value of the delay monitor circuit 501 from the output of the counter 103 (Step 3). Additionally, the CPU 508 measures the VDD voltage with the ADC 513. The ADC 513 is connected to VDD. The ADC 513 monitors the drive voltage of the circuit to be monitored by switching with a switch. Additionally, the counter 514 is connected to the ADC 513.

The CPU 508 calculates the offset value of the delay monitor circuit threshold from the new count value of the delay monitor circuit 501 obtained in Step 2 and the ADC count value obtained in Step 4 (Step 5). That is, the arithmetic circuit (CPU 508) determines whether the threshold voltage of the delay monitor circuit is appropriate using the voltage monitor circuit. The CPU 508 sets the delay monitor circuit threshold offset in the OPBT (Option Byte) 510 (Step 6). That is, if the threshold voltage is not appropriate, the storage circuit stores the adjustment voltage to adjust the threshold voltage. The storage circuit is a non-volatile memory.

The adder 511 adds the threshold offset to the threshold and outputs it. By doing so, it is possible to provide a semiconductor device that adjusts the characteristics of the circuit in the field, improves yield without taking margins during shipment testing, and reduces test costs.

FIG. 6 shows a flowchart of in-field adjustment. As shown in FIG. 6, first, the reset is released (step S601). Step S601 corresponds to the above Step 1. Next, under the user's VDD conditions, the count of ROSC is started (step S602). Step S602 corresponds to the above Steps 2 and 3 in FIG. 5.

Next, the VDD voltage is measured with the ADC 513 (VMON (Voltage Monitor: voltage monitor circuit)) (step S603). Step S603 corresponds to the above Step 4 in FIG. 5. Next, the conversion value of ADC 513 is compared with the count value of ROSC in the field, and the data at the time of shipment testing is corrected (step S604). Step S604 corresponds to Step 5 in FIG. 5. The user's temperature environment is important, and the VDD may be measured while correcting temperature dependence by connecting a temperature sensor to the ADC 513.

Next, it is determined whether there is a difference between the user count at 0h and the current user count (tep S605). If there is no difference greater than the degradation determination criterion (“No” in step S605), do nothing (NOP(Non-Operation)). If there is a difference greater than the degradation determination criterion (“Yes” in step S605), adjust the threshold count and update the NVM (step S606). Step S606 corresponds to the above Step 6 in FIG. 5.

The flowchart of user utilization after the threshold offset is explained. First, under the user's VDD conditions, the count of ROSC is started (step S607). Next, it is determined whether the measurement data is smaller than the DMON threshold and the DMON threshold offset (step S608). If not smaller (No in step S608), do not detect the VDD voltage (step S609). If smaller (Yes in Step S608), detect a low level of VDD voltage (step S610).

FIG. 7 explains an example where no adjustment is needed, with VDD on the vertical axis and the count of the ring oscillator on the horizontal axis. First, reset the count of the delay monitor circuit 501. At this time, it is 1100 at 1V. For example, the DMON threshold (DMONTH) is 0x44C((1) in FIG. 7).

Next, the count value of DMON is measured and it was 1300 at this time ((2) in FIG. 7). Next, VMON measures the voltage of the delay monitor circuit 501 by using the ADC and it was 1.095V (3).

The amount of degradation is calculated from the data. Extrapolating from the initial value line, it was 1060 counts when VDD was 1V. The degradation determination criterion is 1000, which is 100 degraded from the time of shipment. Since 1060 is greater than 1000, no adjustment is needed((4) in FIG. 7). That is, whether the threshold voltage of the delay monitor circuit 501 is appropriate is determined by whether the threshold voltage at the time of degradation of the delay monitor circuit 501 is greater than the degradation criterion. In determining whether the threshold voltage of the delay monitor circuit 501 is appropriate, the count number of the ring oscillator of the delay monitor circuit at the reference voltage is obtained based on the current count number of the ring oscillator of the delay monitor circuit 501 and the drive voltage of the delay monitor circuit 501 detected by the voltage monitor circuit. Then, it is determined by whether the count number at the reference voltage is greater than the degradation determination criterion.

FIG. 8 explains an example where adjustment is needed, with VDD on the vertical axis and the count of the ring oscillator on the horizontal axis. First, reset the count of the delay monitor circuit 501. At this time, it was 1100 at 1V. For example, DMONTH is 0x44C ((1) in FIG. 8).

Next, the count value of DMON is measured and it was 1180 at this time ((2) in FIG. 8). Next, VMON measures the voltage by using ADC and it was measured as 1.080V ((3) in FIG. 8).

The amount of degradation is calculated from the data. Extrapolating from the initial value line, it was 970 counts when VDD was 1V. The degradation determination criterion is 1000, which is 100 degraded from the time of shipment. Since 970 is less than 1000, adjustment is needed ((4) in FIG. 8). Therefore, when the count number at the threshold voltage is less than the degradation determination criterion, the adjustment voltage is added to the threshold voltage to drive the delay monitor circuit.

By adding the delay monitor circuit threshold offset in this way, it is possible to adjust in the field each time degradation occurs.

It should be noted that the present invention is not limited to the above embodiments and can be appropriately modified without departing from the spirit of the invention.

What is claimed is:

1. A semiconductor device comprising:
a delay monitor circuit having a ring oscillator for monitoring the delay of a circuit to be monitored;
a voltage monitor circuit for monitoring the drive voltage of the circuit to be monitored; an arithmetic circuit for determining whether the threshold voltage of the delay monitor circuit is appropriate using the voltage monitor circuit; and
a storage circuit for storing an adjustment voltage to adjust the threshold voltage if the threshold voltage is not appropriate.

2. The semiconductor device according to claim 1,
wherein whether the threshold voltage of the delay monitor circuit is appropriate is determined by whether the threshold voltage at the time of degradation of the delay monitor circuit is greater than the degradation criterion.

3. The semiconductor device according to claim 1,
wherein the determination of whether the threshold voltage of the delay monitor circuit is appropriate is performed by obtaining the count number of the ring oscillator of the delay monitor circuit at the reference voltage based on the current count number of the ring oscillator of the delay monitor circuit and the drive voltage of the delay monitor circuit detected by the voltage monitor circuit, and determining whether the count number at the reference voltage is greater than the degradation determination criterion.

4. The semiconductor device according to claim 3,
wherein when the count number at the threshold voltage is less than the degradation determination criterion, the adjustment voltage is added to the threshold voltage to drive the delay monitor circuit.

5. The semiconductor device according to claim 1,
wherein the voltage monitors circuit measures the voltage of the delay monitor circuit by correcting temperature dependence using a temperature sensor.

6. The semiconductor device according to claim 1,
wherein the storage circuit is a non-volatile memory.

7. A method of driving a semiconductor device,
wherein the delay monitor circuit has a ring oscillator for monitoring the delay of a circuit to be monitored, the voltage monitor circuit monitors the drive voltage of the circuit to be monitored, the arithmetic circuit determines whether the threshold voltage of the delay monitor circuit is appropriate using the voltage monitor circuit, and the storage circuit stores an adjustment voltage to adjust the threshold voltage if the threshold voltage is not appropriate.

8. The method according to claim 7,
wherein whether the threshold voltage of the delay monitor circuit is appropriate is determined by whether the threshold voltage at the time of degradation of the delay monitor circuit is greater than the degradation criterion.

9. The method according to claim 7,
wherein the determination of whether the threshold voltage of the delay monitor circuit is appropriate is performed by obtaining the count number of the ring oscillator of the delay monitor circuit at the reference voltage based on the current count number of the ring oscillator of the delay monitor circuit and the drive voltage of the delay monitor circuit detected by the voltage monitor circuit, and determining whether the count number at the reference voltage is greater than the degradation determination criterion.

10. The method according to claim 9,
wherein when the count number at the threshold voltage is less than the degradation determination criterion, the adjustment voltage is added to the threshold voltage to drive the delay monitor circuit.

11. The method according to claim 7,
wherein the voltage monitors circuit measures the voltage of the delay monitor circuit by correcting temperature dependence using a temperature sensor.

12. The method according to claim 7,
wherein the storage circuit is a non-volatile memory.
